(19) United States
(12) Patent Application Publication
(10) Pub. No.: US 2001/0016413 A1
(43) Pub. Date: Aug. 23, 2001

(54) Semiconductor device and method of manufacturing a semiconductor device with reduced contact failures

(76) Inventors: Kyung-Tae Lee, Seoul (KR); Young-Wug Kim, Suwon-shi (KR)

Correspondence Address: MILLS & ONELLO LLP, Suite 605, Eleven Beacon Street, Boston, MA, 02108, US

(21) Appl. No.: 09/841,652

(22) Filed: Apr. 24, 2001

Related U.S. Application Data
(62) Division of application No. 09/175,088, filed on Oct. 19, 1998.

(30) Foreign Application Priority Data
Mar. 16, 1998 (KR) 98-8792

(51) Int. Cl. H01L 21/4763

(52) U.S. Cl. 438/629; 438/621

(57) ABSTRACT

A semiconductor device and a method of manufacturing a semiconductor device with reduced contact failures are provided. The device includes a semiconductor substrate on which a first insulating layer is formed, the first insulating layer having a first contact hole. A conductive plug is formed in the first contact hole. A second interlevel insulating level is formed on the first insulating layer, the second interlevel insulating layer having a second contact hole with a predetermined width different from the width of the first contact hole. The second contact hole is formed so as to be integrally connected to the first contact hole. A second conductive plug is formed in the second contact hole, and a metallization is formed on a predetermined portion of the second interlevel insulating layer such that it is connected to the second conductive plug.

### RELATED APPLICATIONS

This application is a divisional of copending U.S. application Ser. No. 09/175,088, filed on Oct. 19, 1998, the contents of which are incorporated herein in their entirety by reference.

### BACKGROUND OF THE INVENTION

1. Field of the Invention

The present invention relates to a semiconductor device and a method of fabricating a semiconductor device adapted to reduce or eliminate defects generated during formation of fine contact holes or via holes so as to realize a semiconductor device of large integration and high performance.

2. Discussion of Related Art

As semiconductor integrated circuits become smaller and more dense, technologies for the manufacture of the devices of larger integration are being developed in order to enhance the performance of the devices as well as to minimize the chip size. Accordingly, the processes for forming a fine pattern and an interlevel metal line are considered to be of great significance in the fabrication of semiconductor devices.

Processing a contact hole is normally conducted in such a manner that the contact hole is less than 0.5 micrometer in width and greater than 0.5 micrometer in depth. It is also important to form a conductive plug by the CVD (Chemical Vapor Deposition) method instead of a conventional technique such as metal sputtering or flow method in constructing contact and via holes which are to connect metal lines.

In some cases, the aspect ratio of the final contact hole, i.e., the ratio of the hole's depth to its width, is higher than 2, e.g., in cases where the contact hole is processed to have a width of than 0.5 micrometer and a height of greater than 0.5 micrometer. Consequently, process defects are caused by the limitation of semiconductor fabricating equipment in the etching process for forming the contact hole or in the process of filling a conductive layer to obtain a conductive plug, which restrains the formation of a contact hole less than 0.25 micrometer in width.

This is because where the contact hole has a width below a limited value, the depth of focus of the optic aligner in the photolithography process has a margin so limited as not to obtain a contact hole of a desired shape. Also, under such circumstances, the conductive layer is difficult to fill in a contact hole of high aspect ratio with CVD equipment. In order to overcome the problem, there have been attempts to use improved equipment for fabricating a semiconductor device or vary the process materials for more stable etching and deposition processes. These two methods however have a practical limitation in practicing the actual process.

Under the consideration of such a technological problem, conventional metallization of a semiconductor device and its drawbacks are described below with reference to the sequential diagrams as given in FIGS. 1 to 3. The process for forming a metal line can be divided into three steps according to the following description.

In the first step, as shown in FIG. 1, a gate electrode 102 with a silicide formed thereon is formed at a defined portion in an active region on a semiconductor substrate “s”, e.g., a silicon substrate, having a STI (Shallow Trench Isolation) 100. Using the gate electrode 102 as a mask, an impurity of low concentration is ion-implanted onto the substrate to form a lightly doped impurity region (hereinafter, referred to as “LDD (Lightly Doped Drain)”) 104 in the substrate s on the right and left sides of the gate electrode 102. A spacer 106 consisting of an insulating material is then formed on both sidewalls of the gate electrode 102, and an impurity of high concentration is ion-implanted onto the substrate to form a source/drain region 108 in the substrate s on the right and left sides of the spacer 106.

In the second step, as shown in FIG. 2, an interlevel insulating layer 110 having a specified thickness is formed on the whole surface of the substrate s including gate electrode 102 and spacer 106 and is planarized in the CMP process. Then, a photo-lithography is performed to form a photoresist pattern (not shown) on the interlevel insulating layer 110 in such a manner that the photoresist pattern defines a contact hole region, i.e., defined portions on the gate electrode and on the substrate having the source/drain region formed thereon). The photoresist pattern is used as a mask in etching the interlevel insulating layer 110 to form a contact hole “h”. After the hole h is formed, the photoresist is removed. A conductive layer, which is of a multiple-layered structure having two or three laminated films, is formed on the interlevel insulating layer 110 including the contact hole h by the CVD process and is planarized by the CMP process until the surface of the interlevel insulating layer 110 is exposed, forming a conductive plug 112 in the contact hole h.

In the third step, as shown in FIG. 3, a metal line 114 consisting of metal-metal compounds, Al alloy, Cu alloy or the like is formed at a defined portion on the interlevel insulating layer 110 so as to be connected to the conductive plug 112, finally completing the process.

However, at least the following two problems exist in the above-described process for fabricating a semiconductor device which includes the successive processes such as photolithography, etching, conductive plug formation and metallization.

First, with increasing aspect ratio of the contact hole h, the CD (Critical Dimension) of the pattern gets out of control due to the limited margin in the depth of focus of optic equipment such as an exposure or etching apparatus in the photo-lithography or etching process, so that etching is not adequately conducted in the portion out of the depth of focus of the optic aligner. Thus part of polymer and oxide layer components (for example, PSG and BPSG) constituting the interlevel insulating layer produced in the process remains on the lower portion (reference numeral I in FIG. 3) of the contact hole h after the etching process. Such residuals of polymer or insulating layer do not permit the contact hole h to be completely open after the etching process and accordingly a contact defect occurs in formation of the conductive layer, deteriorating the reliability of the device.

Second, overhangs appear on both edge sidewalls on the contact hole in forming the conductive layer with the CVD method such that when the aspect ratio of the contact hole is large, the upper part of the contact hole is clogged before the contact hole is filled with the conductive layer. Accordingly, after completion of the layer deposition process, the conductive layer inside of the contact hole has voids. Even worse, the conductive layer on the top and bottom portions of the contact hole can be exposed. This becomes more serious with an increase in the aspect ratio of the contact hole, which makes it harder to fill the contact hole with the conductive layer. Further, the voids produced in the conductive layer function as contaminants that increase the resistance of metal lines, deteriorating the electrical operation characteristic of the semiconductor device.

Due to these problems, it is difficult to process the contact hole to have an aspect ratio greater than a specified value. This limits the integration density of the semiconductor device, and the performance of the semiconductor device becomes deteriorated due to the process defects. For example, a contact failure can be caused by the contact hole not open completely.

A deterioration in the operational characteristic can result from the difficulty of the conductive layer filling process.

### SUMMARY OF THE INVENTION

Accordingly, the present invention is directed to a semiconductor device and a method of fabricating a semiconductor device that substantially obviate one or more of the problems due to limitations and disadvantages of the related art.

An object of the present invention is to provide a semiconductor device and a fabricating method which are adapted to eliminate the process defects that occur during formation of fine contact holes or via holes so as to realize a semiconductor device of large integration and high performance.

To achieve these and other objects and in accordance with the purpose of the present invention, the semiconductor device of the invention includes a first insulating layer formed on a semiconductor substrate, the first insulating layer having a first contact hole formed therein. A conductive plug is formed in the first contact hole. A second insulating layer is formed on the first insulating layer and has a second contact hole with a predetermined width different from that of the first contact hole so as to be integrally connected to the first contact hole. A second conductive plug is formed in the second contact hole, and a metallization is formed on a predetermined portion of the second interlevel insulating layer to be connected to the second conductive plug.

In one embodiment, the second contact hole is wider than the first contact hole. Also, the semiconductor substrate can be an insulating substrate in which a conductive pattern is formed. The conductive pattern can include a material such as silicide, an AL alloy or a Cu alloy. Also, the semiconductor substrate can be SOI.

In one embodiment, the first and second insulating layers have a single-layered structure. In another embodiment, a multiple-layered structure of BPSG, PSG, USG and SOG is used. The first and second conductive plugs can comprise Ti, TiN, TiW, TaN, W, Al, alloy and/or Cu alloy. In one embodiment, if the first and second conductive plugs comprise W, Cu or Al, a metal barrier layer is formed in the first and second contact holes. In one embodiment, the metal barrier layer has a single-layered structure of Co. In another embodiment, a multiple-layered structure of Ti/TiN, Ti/TiW or Ti/TaN is used.

In another aspect, according to the fabricating method of the invention, a first insulating layer having a first contact hole formed therein is formed on a semiconductor substrate. A conductive plug is formed in the first contact hole. A second insulating layer having a second contact hole to be integrally connected to the first contact hole is formed on the first insulating layer. A second conductive plug is formed in the second contact hole. A metallization is formed on a predetermined portion of the second insulating layer to be connected to the second conductive plug.

Here, the upper and lower contact holes can be made to have the same width. Alternatively, they can have different widths. Preferably, the upper contact hole is wider than the lower contact hole.

In one embodiment, the conductive pattern comprises an Al alloy material and/or a Cu alloy material. The semiconductor substrate can be made of SOI.

In one embodiment, the first insulating layer is formed by forming the first insulating layer on the surface of the semiconductor substrate where the conductive pattern is formed. An SOG having a specified thickness is formed on the first insulating layer. The first insulating layer is planarized by etching back the SOG. A second insulating layer is formed on the planarized first insulating layer and SOG. A photoresist pattern defining the contact hole is formed on the second insulating layer, and the first and second insulating layers and SOG are selectively etched by using the photoresist pattern as a mask, thereby forming the first contact hole having the structure making contact with the conductive pattern and the substrate.

In another embodiment, the first insulating layer is formed by forming the first insulating layer on the surface of the semiconductor substrate where the conductive pattern is formed. Next, a photoresist layer having a specified thickness is formed on the first insulating layer. The first insulating layer is then planarized by etching back the photoresist layer, and the remaining photoresist layer is removed at a step portion of the planarized first insulating layer. A second insulating layer having a specified thickness is formed on the first insulating layer, and another photoresist pattern defining the contact hole is formed on the second insulating layer. The first and second insulating layers are selectively etched using the photoresist pattern as a mask, thereby forming the first contact hole having the structure making contact with the conductive pattern in the substrate.

In another alternative embodiment, the first insulating layer is formed by forming the first insulating layer on the surface of the semiconductor substrate where the conductive pattern is formed and planarizing the first insulating layer using a chemical mechanical polishing (CMP) process. A photoresist pattern defining the contact hole is formed on the planarized first insulating layer. The first insulating layer is then selectively etched using the photoresist pattern as a mask, thereby forming the first contact hole having the structure making contact with the conductive pattern in the substrate.

In one embodiment, after forming the first insulating layer, the structure is heat treated in a range of temperature of 700 to 900° C.

In one embodiment, the first and second insulating layers have a single-layered structure. In another embodiment, a multiple-layered structure of BPSG, PSG, USG and SOG is used.

As noted above, in one embodiment, the first and second contact holes are made to have different widths or diameters. In one specific embodiment, the second contact hole is 1.0-2.5 times wider than the first contact hole.

In one embodiment, the first conductive plug is formed by forming a conductive layer on the first insulating layer. Next, the conductive layer is planarized using a CMP process to selectively leave the conductive layer only in the first contact hole.

In one embodiment of the method, the first and second conductive plugs are made from at least one of the following materials: Ti, TiN, TiW, TaN, W, Al alloy, and Cu alloy. In one particular embodiment, when the first and second conductive plugs include W, Cu, or Al, a metal barrier layer is formed in the first and second contact holes. The metal barrier layer can be a single-layered structure of Co. In another embodiment, a multiple-layered structure of Ti/TiN or Ti/TiW is used.

In accordance with the invention, the contact hole, or the via hole, is formed by a multiple etching process other than single etching process using the photoresist pattern as a mask, so that when forming respective contact holes, the interlevel insulating layer in contact with the semiconductor substrate can be thinner than insulating layers in prior devices. Accordingly, the photoresist pattern formed on the interlevel insulating layer can be also made thinner, so that a margin can be made deeply in the focus of the optic aligner. Consequently, the fine contact hole(or via hole) can be fabricated without the photolithography process or the process defects often generated in the photolithography process. Additionally, as the conductive layer is deposited in a contact hole that is shallower than conventional holes, it is easier to fill the conductive layer in the contact hole and to minimize the void generation rate.

### BRIEF DESCRIPTION OF THE ATTACHED DRAWINGS

The foregoing and other objects, features, and advantages of the invention will be apparent from the following more particular description of preferred embodiments of the invention, as illustrated in the accompanying drawings in which like reference characters refer to the same parts throughout the different views. The drawings are not necessarily to scale, emphasis instead being placed upon illustrating the principles of the invention.

FIGS. 1 to 3 are schematic cross-sectional diagrams illustrating a conventional method of forming a semiconductor device.

FIGS. 4 to 10 are schematic cross-sectional diagrams illustrating one embodiment of a method of forming a semiconductor device according to the present invention.

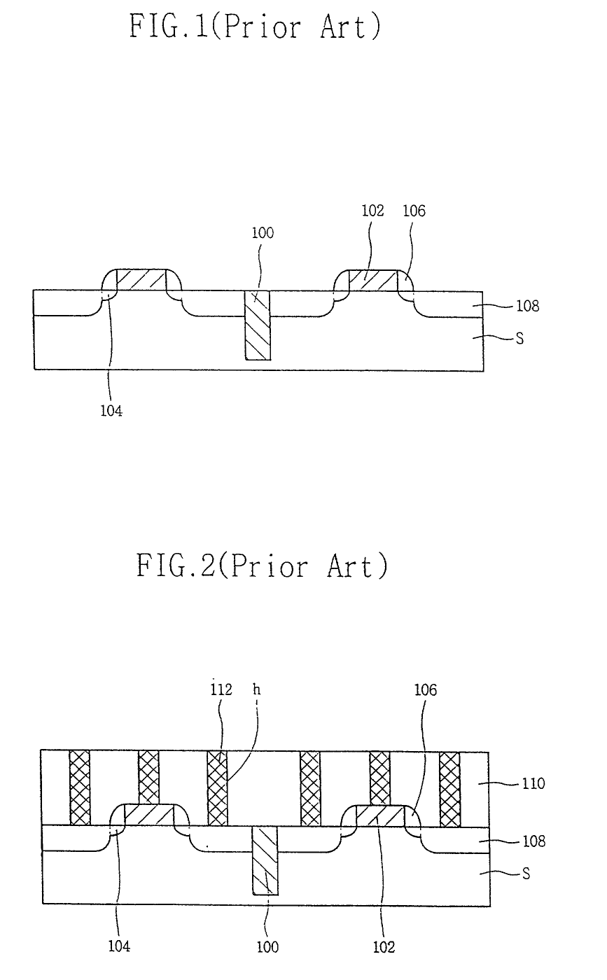

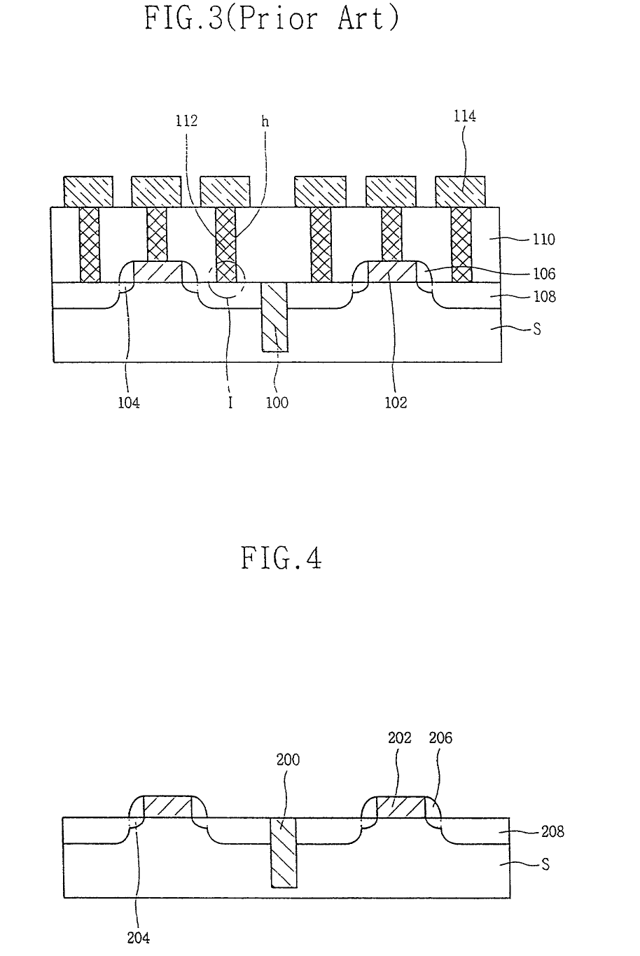

### DETAILED DESCRIPTION OF PREFERRED EMBODIMENT

Reference will now be made in detail to the preferred embodiments of the present invention, examples of which are illustrated in the accompanying drawings.

In accordance with the present invention, a contact hole (or via hole) electrically connecting a semiconductor substrate with a conductor (or connecting two conductors) is formed by a multi-step photolithography processes and dry etching process, not by a single step photolithography process and dry etching process, in order to eliminate the process defects generated in forming the contact hole with a large aspect ratio because of the limitation of the fabricating equipment such as exposing and etching devices.

With reference to FIGS. 4 to 10, the technique of the invention will be described below in detail. FIGS. 4 to 10 are sequential schematic cross-sectional diagrams illustrating one embodiment of the semiconductor fabricating method of the invention. As illustrated in FIG. 4, a gate electrode 202 including polysilicon is formed on a predetermined portion of an active region in a semiconductor substrate (for example, a silicon substrate) “s” having a shallow trench isolation (STI) 200. An impurity of a low concentration is ion implanted into the substrate s using the electrode as a mask to form an LDD region 204 in the substrate s on both sides of the gate electrode. Thereafter, an insulating layer is formed on the overall surface of the substrate including the gate electrode 202, and is anisotropically dry-etched to form the insulating spacer 206 on both side walls of the gate electrode 202. An impurity of a high concentration is ion implanted into the substrate to form the source/drain region 208 in the substrate s on both sides of the spacer 206.

Next, as illustrated in FIG. 5, a first interlevel insulating layer 210 having a specified thickness is formed on the overall surface of the substrate s including the gate electrode 202 and the spacer 206. The layer is heat treated at a temperature of 700 to 900° C. to increase the layer quality planarizing significance, and is planarized by a CMP process. In this embodiment, the first interlevel insulating layer 210 is formed to have a single-layered structure. A multiple-layered structure including material such as BPSG(boron phospho silicate glass), PSG(phospho silicate glass), USG (undoped silicated glass) or NSG (nondoped silicate glass) or SOG (spin on glass) can also be used. Here, the heat-treatment can be omitted. Thereafter, a photoresist pattern 212 defining the contact hole is formed on the interlevel insulating layer 210 by a photolithography process. The interlevel insulating layer 210 is dry-etched, exposing the surface of the gate electrode 202 having the silicide and a predetermined portion of the substrate s by using the photoresist pattern as a mask, so that a first contact hole h1 is formed.

Here, the first contact hole h1 can be fabricated by an SOG etch-back process or a photoresist pattern etch-back process to thereby planarize the first interlevel insulating layer 210. And, in this case, the contact hole is formed in the following manner.

First, an example with application of the SOG etch-back process will be described in three steps a to c. In step a, a first insulating layer (not shown) is formed on the overall surface of the substrate s having the gate electrode 202 and the spacer 206. SOG having a specified thickness is formed thereon and heat-treated. In step b, the SOG is etched back so that the first insulating layer on the gate electrode 202 remains, having a specified thickness. A second insulting layer(not shown) is formed on the first insulating layer and on the SOG planarized by the etch-back process. In step c, the photoresist pattern 212 defining the contact hole formation part is formed on the second insulting layer. The second insulating layer, SOG and the first insulating layer are selectively etched by using the photoresist pattern as a mask so that the first contact hole h1 makes contact with the gate electrode 202 and the substrate s.

The other approach using the photoresist pattern etch-back process will be described in three steps a to c. In step a, the first insulating layer(not shown) is formed on the overall surface of the substrate s having the gate electrode 202 and spacer 206, and the photoresist pattern having a specified thickness is formed thereon. In step b, the photoresist layer is etched back so that the first insulating layer having a specified thickness remains on the gate electrode 202. The photoresist pattern remaining on the step part between the first insulating layers is removed in the etching process, and the second insulating layer having a specified thickness is formed on the overall surface of the first insulating layer. In step c, the photoresist pattern defining the contact hole is formed on the second insulating layer. Using the pattern as a mask, the first and second insulating layers are selectively etched so as to form the first contact hole h1 which makes contact to the gate electrode 101 and the substrate s.

In both of the approaches, for enhancing the planarization characteristic, a predetermined heat treatment, for instance at 700 to 900° C., can be performed after forming the second insulating layer.

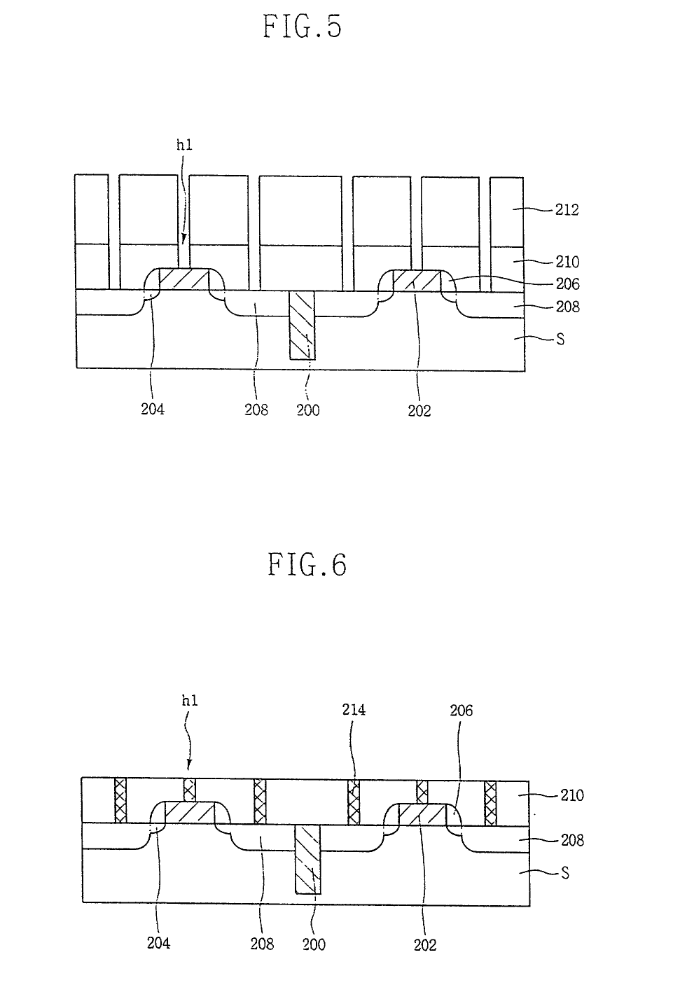

As illustrated in FIG. 6, the photoresist pattern 212 is removed and a conductive layer, which can be made of Ti, TiN, TiW, TaN, W, Al alloy or Cu alloy, is deposited on the first interlevel insulating layer 210 including the first contact hole h1 in a CVD method. Thereafter, the conductive layer is planarized in a CMP process to remain only in the first contact hole h1. Consequently, first conductive plugs 214 made of the above-mentioned material are formed in the first contact holes h1.

In the case in which the first conductive plugs 214 are made of W, Cu or Al, a metal barrier layer(not shown) having the multiple-layered structure of Ti/TiN, TI/TiW, Ti/TiN or the single-layered structure of Co can be formed in the first contact holes h1.

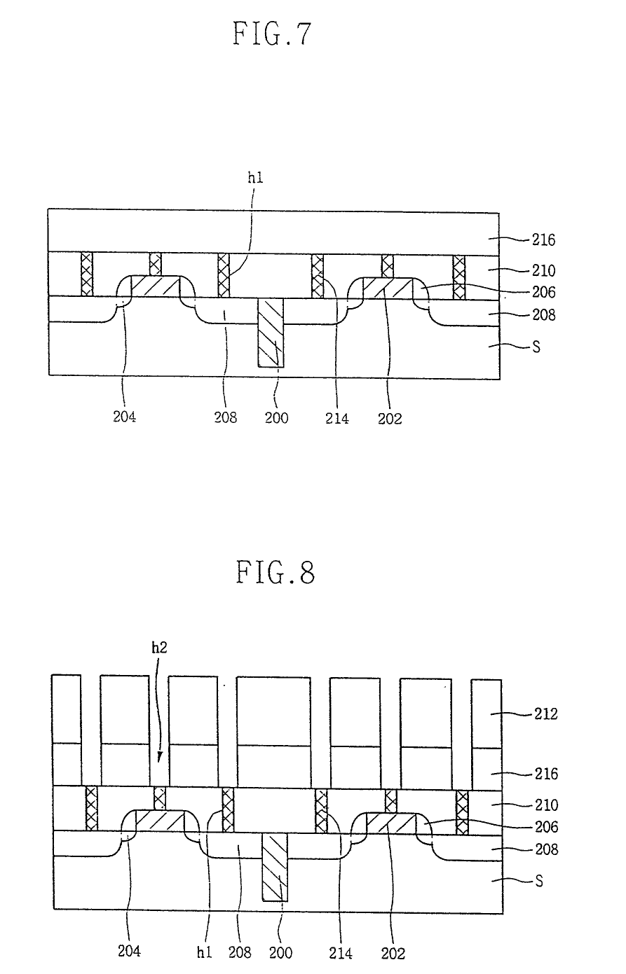

As illustrated in FIG. 7, the second interlevel insulating layer 216 is formed on the first interlevel insulating layer 210 including the first conductive plugs 214.

As illustrated in FIG. 8, a photoresist pattern 212 is formed in such a manner that the surface of the second interlevel insulating layer 216 on the first contact hole h1 is partially exposed using the photolithography process. Using the photoresist pattern as a mask, the second interlevel insulating layer 216 is dry-etched. As a result, second contact holes h2 are integrally connected to the first contact holes h1.

Here, the first and second contact holes h1 and h2 may be fabricated to have different widths. In one embodiment, the second contact hole h2 is made to be 1-2.5 times wider than the first contact hole h1. Alternatively, contact holes can be made to have the same width.

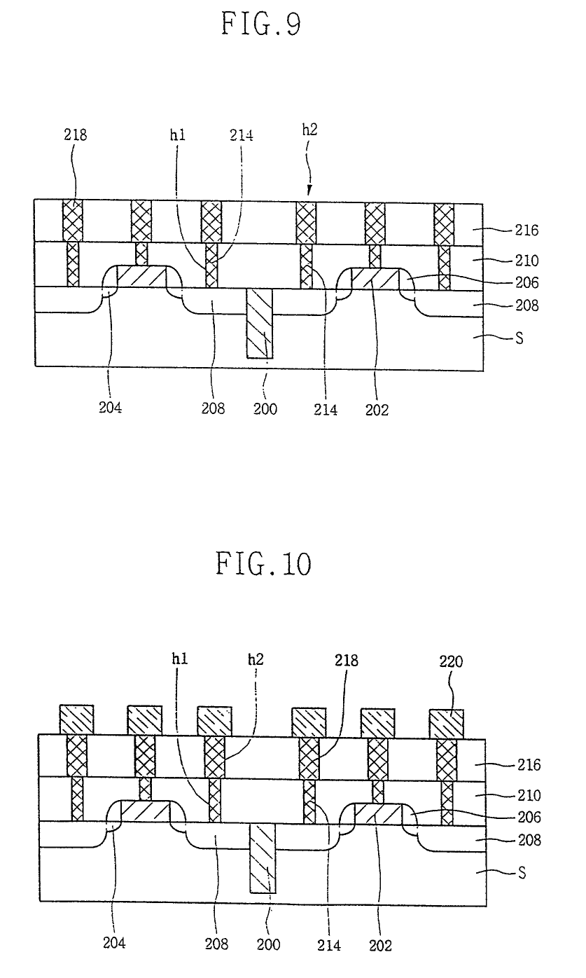

As illustrated in FIG. 9, the photoresist pattern 212 is removed. A conductive layer, which can be made of Ti, TiN, TiW, TaN, W, Al alloy or Cu alloy, is deposited on the second interlevel insulating layer 216 including the second contact hole h2 in a CVD method. Thereafter, the conductive layer is planarized in a CMP process so as to form second conductive plugs 218 in the second contact holes h2.

As illustrated in FIG. 10, a metallization 220 made of Al alloy or Cu alloy is formed on a predetermined portion of the second interlevel insulating layer 216 so as to be connected to the second conductive plugs 218, completing the present fabricating process.

As described above, where the contact holes are made by a multi-step photolithography process and dryetching process, the first and second interlevel insulating layers 210 and 216 making contact with the substrates can be made thinner than conventional layers even though a contact hole having a large aspect ratio is required for the fabrication of semiconductor devices, so that the etching time for the first and second contact holes h1 and h2 becomes shorter and thus the photoresist pattern 212 can be also made thinner. Therefore, the depth of focus of the optic aligner has a margin so that fine pattern fabrication can be achieved. Furthermore, the process for filling the conductive layer inside the first and second contact holes h1 and h2 is performed more easily so that the rate of void generation is minimized, thus improving the quality of the layer. Additionally, the number of multiple-layered metal lines required in fabricating highly integrated semiconductor devices is drastically reduced because of a plurality of contact holes having the multiple-layered structure, thereby realizing large integration and high performance of semiconductor devices.

As illustrated in FIG. 10, the semiconductor device according to the invention is fabricated in the following steps. The first interlevel insulating layer 210 having the first contact hole h1 is formed on the semiconductor substrate s. Next, the first conductive plug 214 is formed in the first contact hole h1. The second interlevel insulating layer 216 having the second contact hole h2 which is integrally connected to the first contact hole h1 is then formed on the first interlevel insulating layer 210. The second conductive plug 218 is formed in the second contact hole h2. The metallization 220 is formed on the predetermined portion of the second interlevel insulating layer 216 so as to be connected to the second conductive plug 218.

Here, for the semiconductor substrate s, besides the above-mentioned silicon substrate, there can be used an insulating substrate having SOI or a predetermined conductive pattern, for example, a gate electrode 202 in which a silicide is formed on the upper part and a spacer 206 of an insulating layer is formed on the side wall, or a metallization made of Al alloy or Cu alloy. This is because the process of forming the contact hole according to the present invention is not restricted only to the process for connecting the semiconductor substrate with a conductor line, but the present invention can be applied in the same manner to form a via hole which connects the silicide with the conductor line or between conductor lines.

As described above, the present invention provides a method of fabricating the contact hole (or via hole) of a largely integrated semiconductor device through a multiple-step etching process, as opposed to a single-step photolithography or dry etching process. This approach of the invention produces the following effects. First, when forming each contact hole, as the interlevel insulating layer making contact with the semiconductor substrate and the photoresist pattern formed thereon becomes thinner than conventional ones, the process defects caused by the limitation in the focus depth margin of the optic aligner (for example, a contact failure caused by the contact hole not open completely) can be prevented so that the fine contact hole formation is realized. Second, as it is easier to fill in the contact hole with the conductive layer, the present invention minimizes generation of voids. Third, the distance between the conductive layers becomes larger, such that the deterioration in speed of the semiconductor device because of the capacitance of the insulating layer is reduced, thereby allowing for realization of large integration and high performance of the semiconductor device.

While this invention has been particularly shown and described with references to preferred embodiments thereof, it will be understood by those skilled in the art that various changes in form and details may be made therein without departing from the spirit and scope of the invention as defined by the appended claims.

What is claimed is:

1. A method of fabricating a semiconductor device, comprising the steps of:
forming a first insulating layer having a first contact hole on a semiconductor substrate where a conductive pattern is formed;
forming a conductive plug in the first contact hole;
forming a second insulating layer on the first insulating layer, the second insulating layer having a second contact hole to be integrally connected to the first contact hole;
forming a second conductive plug in the second contact hole; and
forming a metallization on a predetermined portion of the second insulating layer so as to be connected to the second conductive plug.

2. The method as claimed in claim 1, wherein the conductive pattern comprises one of an Al alloy material and a Cu alloy material.

3. The method as claimed in claim 1, wherein the semiconductor substrate is made of SOI.

4. The method as claimed in claim 1, wherein the step of forming the first insulating layer having the first contact hole on the semiconductor substrate having the conductive pattern comprises the steps of:
forming a first insulating layer on the overall surface of the semiconductor substrate where the conductive pattern is formed;
forming an SOG having a specified thickness on the first insulating layer;
planarizing the first insulating layer by etching back the SOG;
forming a second insulating layer on the planarized first insulating layer and SOG;
forming a photoresist pattern defining the contact hole on the second insulating layer; and
selectively etching the second and first insulating layers and SOG by using the photoresist pattern as a mask, and thereby forming the first contact hole having the structure making contact with the conductive pattern and the substrate.

5. The method as claimed in claim 1, wherein the step of forming the first insulating layer having the first contact hole on the semiconductor substrate having the conductive pattern comprises the steps of:
forming a first insulating layer on the overall surface of the semiconductor substrate where the conductive pattern is formed;
forming a photoresist layer having a specified thickness on the first insulating layer;
planarizing the first insulating layer by etching back the photoresist layer;
removing the photoresist layer remaining in a step portion of the planarized first insulating layer;
forming a second insulating layer having a specified thickness on the first insulating layer;
forming a photoresist pattern defining the contact hole on the second insulating layer; and
selectively etching the second and first insulating layers by using the photoresist pattern as a mask, and thereby forming the first contact hole having the structure making contact with the conductive pattern and the substrate.

6. The method as claimed in claim 5, further comprising a step of heat-treating in the range of temperature of 700-900° C. after forming the second insulating layer.

7. The method as claimed in claim 4, further comprising a step of heat-treating in the range of temperature of 700-900° C. after forming the second insulating layer.

8. The method as claimed in claim 1, wherein the step of forming the first insulating layer having the first contact hole on the semiconductor substrate where the conductive pattern is formed comprises the steps of:
forming the first insulating layer on the overall surface of the semiconductor substrate where the conductive pattern is formed;
planarizing the first insulating layer in CMP process;
forming a photoresist pattern defining the contact hole on the planarized first insulating layer; and
selectively etching the first insulating layer by using the photoresist pattern as a mask, and thereby forming the first contact hole having the structure making contact with the conductive pattern and the substrate.

9. The method as claimed in claim 8, further comprising a step of heat-treating in the range of temperature of 700-900° C. after forming the first insulating layer.

10. The method as claimed in claim 1, wherein the first and second insulating layers have a single-layered structure.

11. The method as claimed in claim 1, wherein the first and second insulating layers have a multiple-layered structure of BPSG, PSG, USG and SOG.

12. The method as claimed in claim 1, wherein the first and second contact holes are made to have different widths.

13. The method as claimed in claim 1, wherein the second contact hole is 1.0-2.5 times wider than the first contact hole.

14. The method as claimed in claim 1, wherein the step of forming the first conductive plug in the first contact hole comprises the steps of:
forming a conductive layer on the first insulating layer having the first contact hole; and
planarizing the conductive layer in CMP process so as to selectively leave the conductive layer only in the first contact hole.

15. The method as claimed in claim 14, wherein the first and second conductive plugs include a material selected from among Ti, TiN, TiW, TaN, W, Al alloy and Cu alloy.

16. The method as claimed in claim 15, further comprising a step of forming a metal barrier layer in the first and second contact holes when the first and second conductive plugs are made of W, Cu or Al.

17. The method as claimed in claim 16, wherein the metal barrier layer has a single-layered structure of Co.

18. The method as claimed in claim 16, wherein the metal barrier layer has a multiple-layered structure of Ti/TiN or Ti/TiW.
